(19) United States
(12) Patent Application Publication
(10) Pub. No.: US 2025/0054898 A1
(43) Pub. Date: Feb. 13, 2025

(54) BUFFER LAYER FOR CHIPS ON WAFER SEMICONDUCTOR DEVICE ASSEMBLIES

(71) Applicant: Micron Technology, Inc., Boise, ID (US)

(72) Inventors: Wei Zhou, Boise, ID (US); Bret K. Street, Meridian, ID (US); Akshay N. Singh, Boise, ID (US)

(21) Appl. No.: 18/789,266

(22) Filed: Jul. 30, 2024

Related U.S. Application Data
(60) Provisional application No. 63/531,225, filed on Aug. 7, 2023.

(51) Int. Cl. H01L 23/00; H01L 23/31; H01L 25/00; H01L 25/065; H10B 80/00

(52) U.S. Cl. CPC H01L 24/32; H01L 24/16; H01L 24/73; H01L 24/81; H01L 24/83; H01L 24/92; H01L 25/0657; H01L 25/50; H01L 23/3107; H01L 24/17; H01L 24/33; H01L 24/97; H01L 2224/16145; H01L 2224/16225; H01L 2224/17181; H01L 2224/26155; H01L 2224/32013; H01L 2224/32145; H01L 2224/32225; H01L 2224/33181; H01L 2224/73204; H01L 2224/81203; H01L 2224/83203; H01L 2224/9201; H01L 2224/97; H01L 2225/06513; H01L 2225/06517; H10B 80/00

(57) ABSTRACT

A semiconductor device, including a lower semiconductor die, one or more upper semiconductor dies disposed over the lower semiconductor die, a non-conductive fillet material disposed between adjacent semiconductor dies of the lower semiconductor die and the one or more upper semiconductor dies, the non-conductive fillet material having edge regions that squeeze out from space between adjacent semiconductor dies, a dielectric layer disposed on a backside of the lower semiconductor die and under the one or more upper semiconductor dies, a buffer layer disposed above the dielectric layer and in contact to at least one edge region of the non-conductive fillet material, and an encapsulant material disposed on sidewalls and top surface of the semiconductor device, the encapsulant material encapsulating the lower semiconductor die and the one or more upper semiconductor dies.

### CROSS-REFERENCE TO RELATED APPLICATION(S)

The present application claims priority to U.S. Provisional Patent Application No. 63/531,225, filed Aug. 7, 2023, the disclosure of which is incorporated herein by reference in its entirety.

### TECHNICAL FIELD

The present disclosure generally relates to semiconductor devices, and more particularly relates to forming buffer layers for chips on wafer (CoW) semiconductor device assemblies.

### BACKGROUND

Semiconductor packages typically include a semiconductor die (e.g., memory chip, microprocessor chip, imager chip) mounted on a substrate or an interface wafer and encased in a protective covering (e.g., an encapsulating material). The semiconductor die may include functional features, such as memory cells, processor circuits, or imager devices, as well as bond pads electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies.

### BRIEF DESCRIPTION OF THE DRAWINGS

FIG. 1 depicts a cross sectional view of a semiconductor device assembly.

FIGS. 2A through 2F illustrate stages of forming a buffer layer on an interposer fabric wafer for semiconductor device assembly in accordance with embodiments of the present technology.

FIGS. 3A through 3F illustrate alternative stages of forming the buffer layer on an interposer fabric wafer for semiconductor device assembly in accordance with embodiments of the present technology.

FIG. 4 illustrates a stage of bonding semiconductor die stacks on an interposer fabric wafer for semiconductor device assembly in accordance with embodiments of the present technology.

FIG. 5 illustrates a cross sectional view of a semiconductor device assembly with a buffer layer in accordance with embodiments of the present technology.

FIG. 6 is a flow chart illustrating a method of processing semiconductor device assemblies in accordance with embodiments of the present technology.

FIG. 7 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

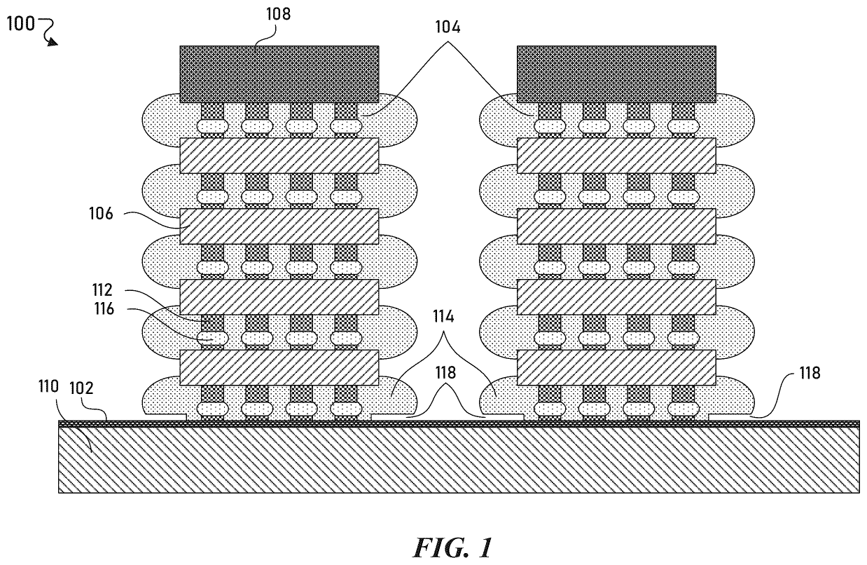

CoW assembly is a promising technology for advanced semiconductor device packaging applications. It can be used to overcome the limitations of Wafer-to-Wafer (WoW) bonding and improve die stacking process yield and bonding placement accuracy. CoW assembly can also be adopted for a higher semiconductor device density with reduced package size. FIG. 1 depicts a cross sectional view of a semiconductor device assembly utilizing the CoW assembly technique. In this example, memory die stacks have been bonded onto an interposer fabric (IF) wafer 110 using thermal compression bonding technique by applying pressure and heat. Here, the memory die stacks may include a plurality of core memory dies 106 and a top memory die 108 that is disposed above the plurality of core memory dies 106. Each one of the plurality of core memory dies 106 and the top memory die 108 can be interconnected through contact pads 112 and solder balls 116. The solder balls 116 can be disposed between corresponding contact pads for electrical interconnection.

As shown on FIG. 1, non-conductive fillet (NCF) material 104 can be flowed into the memory die stacks and the gap between the memory die stacks and the IF wafer 110 to enhance the adhesion therebetween. Once the NCF material 104 is applied to the semiconductor device assembly 100, the IF wafer 110 and the memory die stacks are subjected to pressure and heat in a compression bonding stage, which activates the NCF material 104 to make it soften and adhere to the memory dies and the IF wafer 110. During the compression bonding and post bonding stages such as cooling and consolidation, the NCF material 104 may inevitably squeeze out of the memory die stacks and the gap between the memory die stacks and the IF wafer 110. As shown on FIG. 1, the squeezed out NCF 114 may extend horizontally out of the sidewalls of memory die stacks. Because only partially cured, the squeezed out NCF 114 has a degraded adhesion to the dielectric layer 102, e.g., a silicon nitride film, that is disposed on the back side surface of the IF wafer 110. The poor adhesion between the squeezed out NCF 114 and dielectric layer 102 may cause gaps 118 disposed there between. Moreover, the dielectric layer 102 under the squeezed out NCF 114 will sustain a high stress during the curing stage of the thermal compression bonding process, which may cause cracks or delamination of the dielectric layer 102 during a downstream CoW assembly singulation process.

The cracks and delamination of dielectric layer 102 formed during the semiconductor device assembly can introduce resistance, impedance variation, and discontinuities in signal paths to degrade the semiconductor device electrical performance. Moreover, the cracks and film delamination defects can affect the thermal dissipation of the semiconductor device, leading to localized hotspots or inefficient heat transfer. To address these challenges and others, the present technology applies a buffer layer above the dielectric layer for the CoW assemblies. In particular, the buffer layer can be disposed between neighboring memory cube regions to form a direct contact with squeezed out NCF material during the thermal compression bonding process. Organic polymer materials such as benzocyclobutene (BCB) and Polyimide (PI) can be included in the buffer layer so as to provide an enhanced adhesion with the squeezed out NCF material. The direct contact and improved adhesion between the squeezed out NCF material can effectively reduce the chance of generating gaps therebetween. In addition, high stresses formed during the thermal compression bonding process can be transferred from the dielectric layer to the buffer layer, to protect the dielectric layer from crack or delamination during the semiconductor device assemblies.

For the semiconductor device assemblies of the present technology, the buffer layer can be fabricated before bonding the semiconductor die stacks on the IF wafer. In particular, the buffer layer can be formed on a dielectric layer disposed on the backside surface of the IF wafer. In some embodiments, a hard mask layer can be patterned above the dielectric layer and the buffer layer can be coated on exposed dielectric layer regions on the IF wafer. In some other embodiments, the buffer layer can be coated across the surface of the dielectric layer and then selectively removed from memory cube regions in which semiconductor die stacks are bonded on the IF wafer.

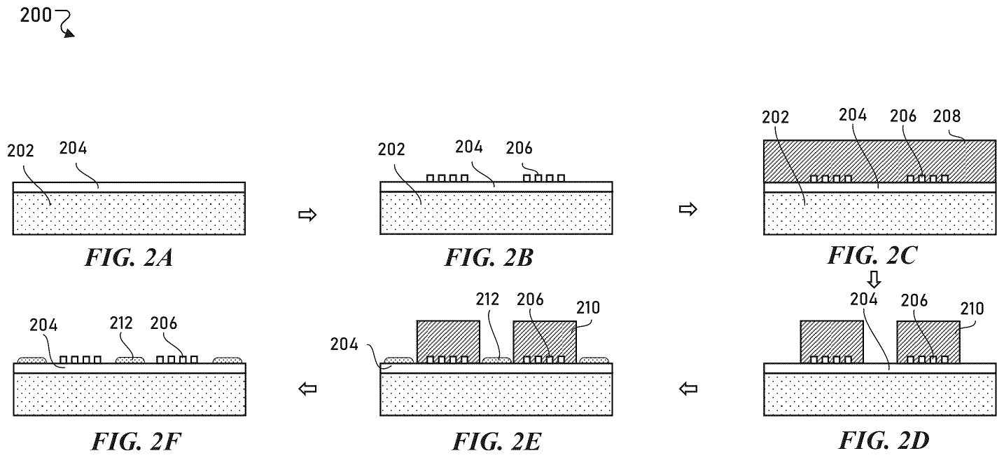

FIGS. 2A through 2F illustrate stages of forming a buffer layer 212 on IF wafer 202 for semiconductor device assembly in accordance with embodiments of the present technology. In this exemplary route, a hard mask layer 208 can be adopted to pattern a surface of a dielectric layer 204, exposing certain regions to allow the buffer layer 212 to be coated thereon. This route starts with forming the dielectric layer 204 on the IF wafer 202. For example, as shown in FIG. 2A, the dielectric layer 204 can be coated on a back side surface of the IF wafer 202. The dielectric layer 204 can be deposited using various thin film deposition techniques, such as chemical vapor deposition (CVD), physical vapor deposition (PVD), atomic layer deposition (ALD), spin-on deposition process, and/or a polymer-based deposition process. In addition, the dielectric layer 204 can be made of materials including silicon nitride, silicon oxide, and/or any other types of low-K dielectric materials. The dielectric layer 204 may have a thickness ranging from 100 nm up to 10 μm. Here, the dielectric layer 204 can be configured to protect the backside surface of the IF wafer, and provide mechanical support and electrical isolation.

Once the dielectric layer 204 is coated, contact pads 206 can be fabricated on the backside surface of the IF wafer 202. Notably, the contact pads 206 can be formed through the dielectric layer 204 and are in direct contact to the IF wafer 202. As shown in FIG. 2B, a plurality of contact pads 206 can be formed in each one of the memory cube regions on the backside surface of the IF wafer 202. There may be similar number of contact pads, e.g., a 4×4 pattern of contact pads, formed in each memory cube region to serve as electrical connections between bonded memory stacks and IF die in the final semiconductor device. Notably, the contact pads 206 are thicker than the dielectric layer, having a thickness ranging from 0.5 μm to 10 μm and protruding out of the dielectric layer 204. In this example, the dielectric layer 204 can be patterned and removed from the memory cube regions to expose the backside surface of the IF wafer 202 for contact pads processing. In this example, the contact pads 206 can be made of electrically conductive materials such as copper. Further, the contact pads 206 can be deposited, for example, using CVD, PVD, ALD, plating, electroless plating, spin coating, and/or other suitable techniques.

Alternatively, the contact pads 206 can be fabricated before coating the dielectric layer 204 on the IF wafer 202. For example, the contact pads 206 can be directly fabricated on the incoming IF wafer 202. Specifically, contact pads 206 can be formed on each memory cube regions on a backside surface of the incoming IF wafer 202. Thereafter, the dielectric layer 204 can be deposited on the backside surface of the IF wafer 202, occupying spaces between memory cube regions and gaps between neighboring contact pads.

In the next step, as shown in FIG. 2C, the hard mask layer 208 can be coated on the IF wafer 202, covering the contact pads 206 and the dielectric layer 204. In particular, the hard mask layer 208 can be made of photoresist deposited using a spin coating technique. The photoresist layer may go through a soft bake process to evaporate solvent included in the photoresist, leaving a dry and solid hard mask film 208 on the IF wafer 202. In some other embodiments, the hard mask layer 208 can be made of dielectric materials different to the dielectric layer 204. For example, the hard mask layer 208 can be a silicon oxide layer being coated on the dielectric layer 204 that is made of silicon nitride. Here, the dielectric layer 204 can be used as an etching stop layer when patterning the hard mask layer 208 in downstream processes.

As shown in FIG. 2D, the hard mask layer 208 can be further processed into patterned hard masks 210, covering corresponding memory cube regions and contact pads 206 disposed therein. In some embodiments, the hard mask layer 208 is a photoresist layer, which can be exposed using a photomask containing patterns corresponding to the memory cube regions. Particularly, the hard mask layer 208 can be a positive photoresist. The spaces between the memory cube regions can be exposed to a suitable light source for exposure and to convert the photoresist more soluble. In addition, the exposed photoresist can be stripped off, leaving hard masks 210 that cover corresponding contact pads 206 in the memory cube regions. In some other embodiments, the hard mask layer 208 can be a dielectric layer having different material composition to that of the dielectric layer 204. The hard mask layer 208 can be patterned using a photolithography technique and a suitable etching technique such as a dry etching technique or a wet etching technique. The etching process may stop on the dielectric layer 204 due to a dramatically reduced relative etching rate thereon. The hard mask patterning process described on this stage exposes regions of the dielectric layer 204 that are disposed between neighboring memory cube regions for buffer layer preparation in the downstream.

Once the hard mask layer 208 is patterned, the buffer layer 212 can be coated on the dielectric layer 204. In particular, the buffer layer 212 can be deposited on the exposed regions of the dielectric layer 204. In some embodiments, the buffer layer can be made of organic polymer materials including BCB and PI. The organic polymer materials may have a relatively low coefficient of thermal expansion, good electrical insulation, and be highly resistant to moisture and other environmental factors. Here, the buffer layer 212 may be coated using a spin coating technique or any other suitable techniques. In some other embodiments, the buffer layer can be made of other suitable materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Further, the buffer layer 212 may have a thickness ranging from 0.5 μm to 10 μm, and a width ranging from 10 μm to 300 μm.

In the step showing on FIG. 2F, the hard masks 210 can be removed from the semiconductor device assembly. In some embodiments, the hard mask 210 can be stripped off from the IF wafer 202. In some other embodiments, the hard mask 210 can be selectively removed by a suitable etching process. As shown in FIG. 2F, the buffer layer 212 can be disposed on the dielectric layer 204 and between neighboring memory cube regions that include the contact pads 206. In particular, the buffer layer 212 can surround corresponding memory cube regions on the IF wafer 202, e.g., the buffer layer 212 can be disposed on four edges of corresponding memory cube regions above the dielectric layer 204.

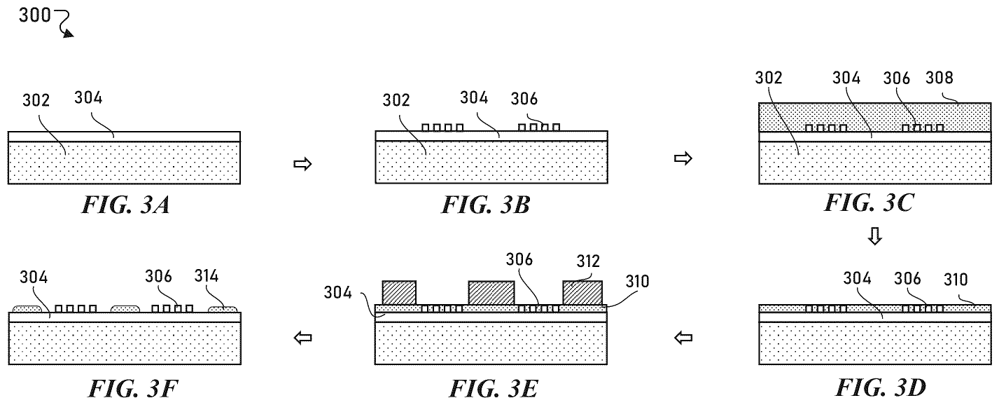

FIGS. 3A through 3F illustrate alternative stages of forming a buffer layer 312 on an IF wafer 302 for semiconductor device assembly in accordance with embodiments of the present technology. In this exemplary route, a continuous layer 308 can be coated on the IF wafer 302 and then patterned to for the buffer layer 312 that only exist on spaces between memory cube regions.

The processes shown on FIGS. 3A and 3B can be similar to the FIGS. 2A and 2B respectively. For example, a dielectric layer 304 can be coated on a back side surface of the IF wafer 302. In addition, contact pads 306 can be fabricated, through the dielectric layer 304, on the backside surface of the IF wafer 202. The contact pads 306 can be processed after removing the dielectric layer material from corresponding memory cube regions. The dielectric layer 304 can be made of materials including silicon nitride or silicon oxide. In addition, the contact pads can be made of conductive materials such as cooper. Alternatively, the contact pads 306 can be directly formed on an incoming IF wafer, before depositing the dielectric layer 304. Once the contact pads are formed, the dielectric layer can be further deposited on a backside surface of the IF wafer 302. In this example, the dielectric layer 304 may have a thickness (e.g., ranging from 100 nm up to 10 μm) less than that of the contact pads (e.g., ranging from 0.5 μm to 10 μm).

Turning to the step shown on FIG. 3C, the continuous layer 308 can be deposited on the IF wafer 302, covering the dielectric layer 304 and the protruding contact pads 306. In some embodiments, the continuous layer 308 can be made of organic polymer materials including BCB and Polyimide PI. In some other embodiments, the continuous layer 308 can be made of materials different to the dielectric layer 304, including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. The continuous layer 308 can be deposited using CVD, PVD, ALD, plating, electroless plating, spin coating, and/or other suitable techniques. Further, the continuous layer 308 may have a thickness higher than that of the protruding contact pads, ranging from 1 μm to 50 μm.

The continuous layer 308 can be further planarized into a continuous buffer layer 310 with a thinner thickness. For example, as shown in FIG. 3D, the continuous layer 308 can be polished to expose a front side surfaces of the contact pads 306. This process can be conducted using a chemical-mechanical polishing (CMP) technique or any other suitable techniques. The polishing process can be precisely controlled using end point detection and automatically stop when it reaches the contact pads 306. In some other embodiments, the continuous buffer layer 310 may have a thickness less or more than the protruding contact pads 306. For example, the front side surface of the continuous buffer layer 310 may be slightly higher or lower than the front side surfaces of the contact pads 306. The continuous buffer layer 310 may have a thickness ranging from 0.5 μm to 10 μm.

Turning to FIG. 3E which illustrate a stage of patterning hard masks 312 above the continuous buffer layer 310. In this example, the patterned hard masks 312 are disposed between neighboring memory cube regions to cover the continuous buffer layer 310 disposed therein. Notably, the edges of the hard masks 312 are separated from the most outside contact pads of corresponding memory cube regions. In addition, the hard masks 312 can be formed to surround corresponding memory cube regions. Once the patterned hard masks 312 are formed, a selectively etching process can be conducted to remove the continuous buffer layer 310 from uncovered regions, i.e., the memory cube regions. A dry chemical etching process or wets etching process that is selective to the dielectric layer 304 can be adopted in this step to remove the buffer layer 310 from the contact pads.

In the last step of this exemplary route, the hard masks 312 can be stripped off from the IF wafer 302. As shown in FIG. 3F, a buffer layer 314 can be formed on the dielectric layer 304 and between neighboring memory cube regions. Moreover, the edges of the buffer layer 314 are away from corresponding contact pads. The buffer layer 314 can surround corresponding contact pads 306 and has a thickness ranging from 0.5 μm to 10 μm. In this example, the buffer layer 314 may have a width ranging from 10 μm to 300 μm along the frontside surface of the dielectric layer 304. In some other embodiments, the hard masks 312 may be patterned only along certain edges of the memory cube regions. As a results, the buffer layer 314 may only surround certain edges of corresponding memory cubes regions.

In other embodiments, the buffer layer included in the semiconductor device assemblies can be made of a same material to the dielectric layer disposed on the back side surface of the IF wafer. For example, both of the buffer layer and the dielectric layer can be made of silicon nitride. In particular, the proposed buffer layer and dielectric layer architecture can be formed through patterning a thick dielectric layer, e.g., a dielectric layer having thickness equal to a sum of the thickness of the buffer layer and dielectric layer. The thick dielectric layer can be firstly deposited on the back side surface of the IF wafer. After that a photolithography patterning process can be conducted to pattern the thick dielectric layer to expose regions corresponding to the memory cube regions. An etching process can be adopted to further reduce the thick dielectric layer thickness until its is same to the proposed dielectric layer thickness. This way, thicker dielectric layer regions disposed on the gaps between neighboring memory cube regions can perform similar to the buffer layer, e.g., assisting in forming direct contact between squeezed out NCF and the buffer layer.

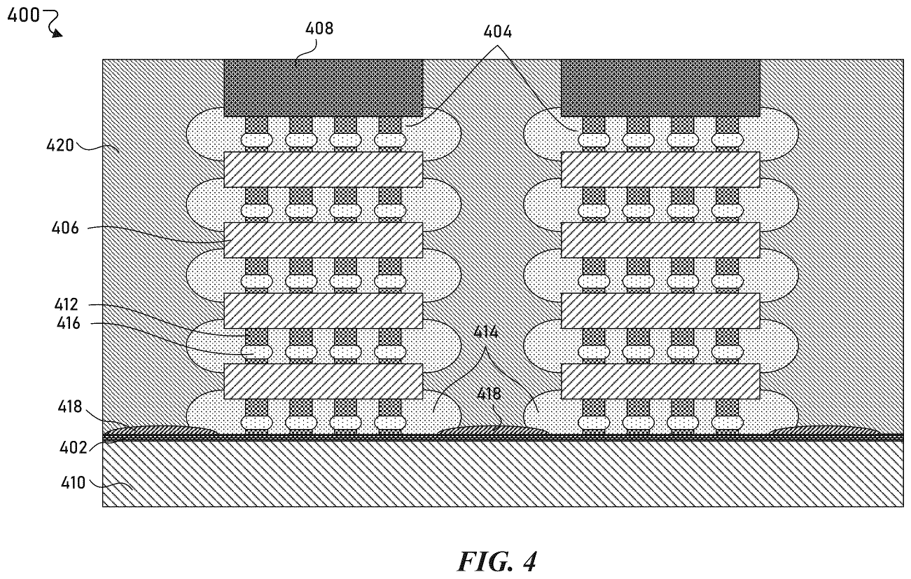

Once the buffer layers are formed on the dielectric layer of the semiconductor device assembly, a CoW packaging process can be applied to bond a plurality of semiconductor die stacks on the IF wafer. For example, FIG. 4 illustrates a stage of bonding semiconductor die stacks on the IF wafer 410 utilizing a thermal compression bonding technique for semiconductor device assembly in accordance with embodiments of the present technology.

In some embodiments, the semiconductor dies included in the semiconductor device assemblies may be stacked through a non-conductive film (e.g., NCF film 404) underfill process. For example, contact pads 412 of an upper semiconductor die (e.g., semiconductor die 406) can be aligned with and attached to contact pads of a lower semiconductor die (e.g., semiconductor die 406′) through solder balls 416 for the solder-contact pad bonding in each of the plurality of semiconductor die stacks. Here, FIG. 4 illustrates a plurality of exemplary memory stacks including a group of core memory dies (e.g., the memory die 406) and a dummy die 408. The dummy die 408 can be disposed above each one of the plurality of stacked memory dies in the memory die stack, and coupled to lower memory dies of the memory die stacks through the corresponding contact pads and solder balls. Alternatively, solder bumps of an upper semiconductor die can be aligned with and attached to a through silicon via (TSV, not shown) of a lower semiconductor die for the solder-TSV bonding in each of the plurality of semiconductor die stacks. In this example, NCF underfill materials can be further flowed into the interface between the stacked semiconductor dies to provide electric isolation between the solder bumps and mechanical support between the stacked dies. In some other embodiments, each of the plurality of semiconductor die stacks may include semiconductor dies stacked on top of each other. Each semiconductor die of the stack may have a frontside facing toward the IF wafer 410, which may be referred to as an active side of the semiconductor die having memory arrays, integrated circuits coupled to the memory arrays, bond pads coupled to the integrated circuits, etc., and a backside opposite to the frontside.

Although the present technology is described herein with semiconductor device assemblies including semiconductor dies or a stack of semiconductor dies attached to a semiconductor wafer (e.g., the IF wafer 410), it should be understood that the principles of the present technology are not limited thereto. For example, a semiconductor device assembly in accordance with the present technology may include a single semiconductor die (e.g., a memory die) attached (or bonded) to an interface wafer.

In some embodiments, the IF wafer 410 may include different types of semiconductor dies (e.g., logic dies, controller dies) than the plurality of semiconductor die stacks included in FIG. 4 (e.g., memory dies, DRAM products). The logic dies of the IF wafer 410 can be configured to exchange electrical signals with the semiconductor dies bonded thereon and with higher level circuitry (e.g., a host device external to the semiconductor device assembly) coupled with the logic dies. In some embodiments, the IF wafer 410 includes interposer dies having various conductive structures (e.g., redistribution layers, vias, interconnects) configured to route electrical signals between the plurality of semiconductor die stacks and higher-level circuitry—e.g., a central processing unit (CPU) coupled with the semiconductor die stacks through the interposer die included in the IF wafer 410.

In the CoW packaging process, the plurality of semiconductor die stacks can be bonded on the back side surface of the IF wafer 410 through the application of heat and pressure there between. Specifically, the contact pads of the lowest semiconductor dies in the semiconductor die stacks can be aligned to and bonded to corresponding contact pads of the IF wafer 410. In this example, the contact pads of the IF wafer 410 protrude out of the dielectric layer 402 and are bonded to contact pads of the plurality of semiconductor die stacks through solder balls 416. Further, the plurality of semiconductor dies stacks can be attached on the dielectric layer 402 of the IF wafer 410 through flowing NCF material there between. As shown in FIG. 4, NCF layer 404 can be filled between the semiconductor dies and into the gap between the IF wafer 410 and the plurality of semiconductor die stacks. A high temperature thermal treatment of the thermal compression bonding process can be further applied on the semiconductor device assembly to cure the NCF material for better gap fill and stronger mechanical support to the semiconductor dies and contact pads connections. In addition, the as-deposited NCF material can be cured for a better electrical insulation, preventing the risk of short circuits or electrical interference within the packaging. In this example, the NCF material 404 may be made of epoxy-based materials, acrylic-based materials, and/or polyimide-based materials.

In some embodiments, the NCF material may squeeze out from the memory cube regions, e.g., the gaps between the plurality of semiconductor die stacks and the IF wafer 410, during and/or after the thermal treatment process. Specifically, squeezed out NCF (labeled as NCF 414 in FIG. 4) may be formed during the cooling and solidification stages of the thermal compression bonding process, and are disposed on sidewalls of each one of the semiconductor die stacks. In fact, the NCF material 414 may be only partially cured during the CoW bonding process. In this example, the buffer layer 418 can be fabricated on the dielectric layer 402 and between neighboring memory cube regions. In addition, the buffer layer 418 may have a thickness less than a height of the gap between the lowest semiconductor die and the IF wafer 410. As a result, the squeezed out NCF 414 will be in a direct contact to the buffer layer 418. Moreover, in this example, the squeezed out NCF 414 can present a better adhesion with organic materials (e.g., BCB and PI) included in the buffer layer 418. In contrast to the gaps 118 formed between squeezed out NCF 114 and the dielectric layer 102 disclosed in FIG. 1, the improved adhesion between the squeezed out NCF 414 and buffer layer 418 reduces the risk of forming gaps or cracks along the dielectric layer 402.

After the plurality of semiconductor die stacks being bonded on the IF wafer 410, encapsulant materials, e.g., mold compound 420 can flow into the CoW semiconductor device assemblies 400 or overflow above the top surface of the plurality of semiconductor die stacks for packaging encapsulation. In particular, the mold compound 420 can be filled into the spaces between neighboring squeezed out NCF material 414. In this example, the mold compound 420 can be made of materials including an epoxy-based liquid compound with granules, an epoxy-based liquid compound without granules, a granular compound, a thin-film based underfill, a thin-film based compound, a resin-based encapsulant, and/or a polymer.

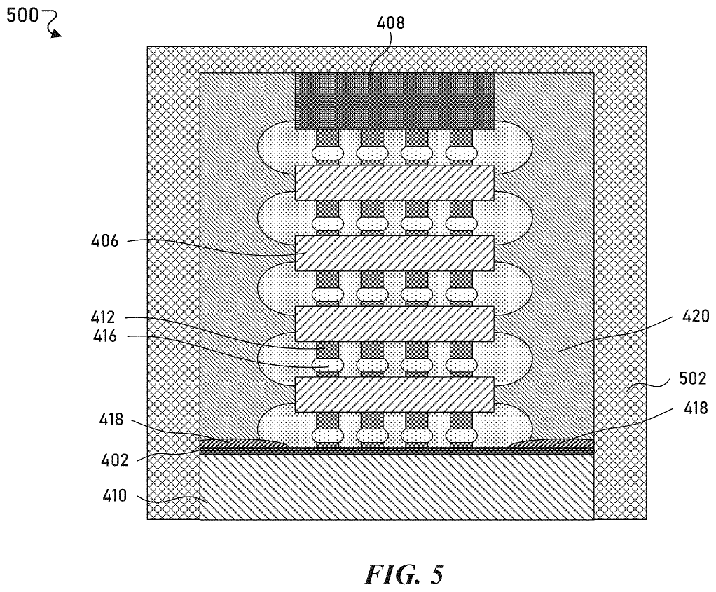

In a next step, as shown in FIG. 5, the semiconductor device assembly 400 can be processed in a singulation process to form separated semiconductor device assemblies 500. Specifically, the IF wafer 410, alongside the dielectric layer 402 and buffer layer 418 disposed thereon, can be sliced into individual IF die 502 for the semiconductor device assembly 500. Here, the singulation can be performed by dicing the IF wafer 410 along the gaps between neighboring semiconductor die stacks and right on the buffer layer 418. The dicing process can be performed using different methods, such as mechanical sawing, laser cutting, or scribing. In the present technology, the dielectric layer 402 is covered by the buffer layer 418, therefore any forces or stresses generated in the dicing process can be undertaken by the buffer layer 418, diverting away from the dielectric layer 402. The configuration of the buffer layer 418 above the dielectric layer 402 protects the dielectric layer 402 against cracking defects during the COW singulation process.

In this example, package perimeter material 502 can be further applied to seal and protect the edges of the semiconductor device assembly. As shown in FIG. 5, the package perimeter material 502 can be disposed above the plurality of semiconductor die stacks and to surround sidewalls of the semiconductor die stacks and the IF wafer 410. Here, non-conductive materials such as an epoxy-based compound or a polymer sealant can be used as the package perimeter material 502. In this example, the package perimeter material 510 can also provide mechanical support, reinforcing the structural integrity of the semiconductor device assembly 500. In some other examples, the semiconductor device assembly 500 does not include the package perimeter material 502. For example, the singulated semiconductor device assembly 500 can be sent for integration with other device components. In this case, the IF wafer 410 sidewall can be exposed and the buffer layer 418 can be observed from the assembly sidewall.

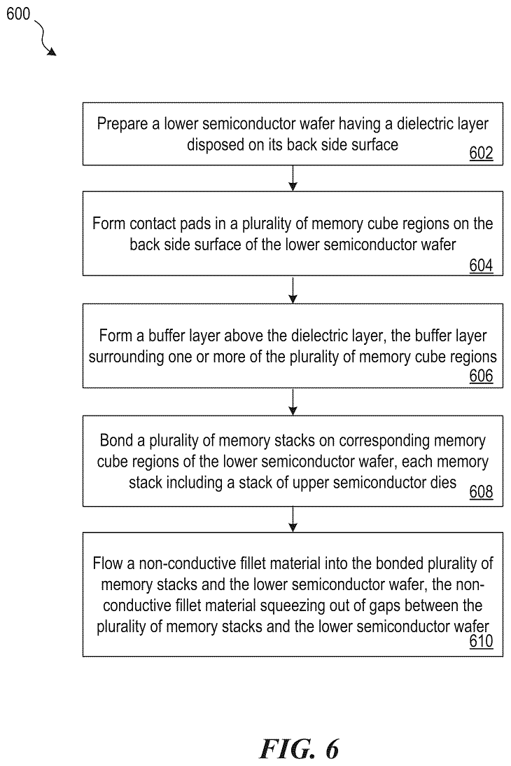

Turning now to FIG. 6 which is a flow chart illustrating a method 600 of processing semiconductor device assemblies according to embodiments of the present technology. The method 600 includes preparing a lower semiconductor wafer having a dielectric layer disposed on its back side surface, at 602. For example, the dielectric layer 204 can be deposited on the backside surface of the incoming IF wafer 202, as shown on FIG. 2A.

The method 600 also includes forming contact pads in a plurality of memory cube regions on the back side surface of the lower semiconductor wafer, at 604. For example, contact pads 206 can be formed using photolithography techniques in the memory cube regions of the IF wafer 202. As shown on FIG. 2B, the contact pads can protrude out of the dielectric layer 204.

In addition, the method 600 includes forming a buffer layer above the dielectric layer, the buffer layer surrounding one or more of the plurality of memory cube regions, at 606. For example, buffer layers 212 can be deposited on the exposed surface regions of the dielectric layer 204 through patterning hard masks to cover the memory cube regions, as shown on FIGS. 2C to 2F. Alternatively, the buffer layers 314 can be formed through depositing the continuous buffer layer 310 and then selectively remove the buffer layer 310 from the memory cube regions, as shown on FIGS. 3C to 3F.

The method 600 further includes bonding a plurality of memory stacks on corresponding memory cube regions of the lower semiconductor wafer, each memory stack including a stack of upper semiconductor dies, at 608. For example, stacked semiconductor dies can be bonded on the back side surface of the IF wafer 410 using the thermal compression bonding technique, as shown on FIG. 4.

Lastly, the method 600 includes flowing a non-conductive fillet material into the bonded plurality of memory stacks and the lower semiconductor wafer, the non-conductive fillet material squeezing out of gaps between the plurality of memory stacks and the lower semiconductor wafer, at 610. For example, NCF material 404 can be flowed into the gaps between semiconductor dies and the gaps between the semiconductor die stacks and the IF wafer 410. During the curing, cooling and solidification stages, the NCF material 414 may squeeze out from above noted gaps and extend horizontally. In particular, the squeezed out NCF can be in a direct contact to the buffer layer 418, as shown on FIG. 4.

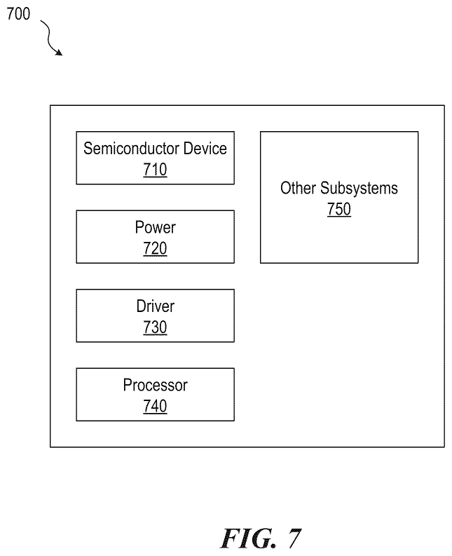

Any one of the semiconductor structures described above with reference to FIGS. 2A-5 can be incorporated into any of a myriad of larger and/or more complex systems, a representative example of which is system 700 shown schematically in FIG. 7. The system 700 can include a semiconductor device 710, a power source 720, a driver 730, a processor 740, and/or other subsystems or components 750. The semiconductor device 710 can include features generally similar to those of the semiconductor devices described above, and can therefore include the buffer layers, e.g., buffer layers 212, 314, and/or 418, described in the present technology. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, and appliances. Components of the system 700 may be housed in a single unit or distributed over multiple, interconnected units (e.g., through a communications network). The components of the system 700 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a lower semiconductor die;
one or more upper semiconductor dies disposed over the lower semiconductor die;
a non-conductive fillet material disposed between adjacent semiconductor dies of the lower semiconductor die and the one or more upper semiconductor dies, the non-conductive fillet material having edge regions that squeeze out from space between adjacent semiconductor dies;
a dielectric layer disposed on a backside surface of the lower semiconductor die and under the one or more upper semiconductor dies;
a buffer layer disposed above the dielectric layer and in contact to at least one edge region of the non-conductive fillet material; and
an encapsulant material disposed on sidewalls and top surface of the semiconductor device, the encapsulant material encapsulating the lower semiconductor die and the one or more upper semiconductor dies.

2. The semiconductor device of claim 1, wherein the buffer layer is lower than a lowest semiconductor die of the one or more upper semiconductor dies, and the buffer layer is in contact to and disposed under at least a portion of bottom surface of a lowest edge region of the squeezed out non-conductive fillet material.

3. The semiconductor device of claim 1, wherein the buffer layer surrounds the one or more upper semiconductor dies.

4. The semiconductor device of claim 1, wherein the buffer layer is made of organic polymer materials including benzocyclobutene (BCB) and Polyimide (PI).

5. The semiconductor device of claim 1, wherein the buffer layer is made of dielectric materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

6. The semiconductor device of claim 1, wherein the dielectric layer is silicon nitride.

7. The semiconductor device of claim 2, wherein the buffer layer is away from a gap between the lower semiconductor die and the one or more upper semiconductor dies.

8. The semiconductor device of claim 2, wherein the buffer layer has a length from edge to center of the semiconductor device ranging from 10 μm to 500 μm, and a thickness ranging from 1 μm to 10 μm.

9. The semiconductor device of claim 1, wherein the lower semiconductor die is an interposer fabric die and the one or more upper semiconductor dies are memory dies.

10. The semiconductor device of claim 1, wherein the lower semiconductor die and the one or more upper semiconductor dies are bonded through contact pads and solder bumps.

11. A semiconductor device, comprising:
a lower semiconductor die;
an upper semiconductor die disposed above and bonded to the lower semiconductor die;
a non-conductive fillet material disposed in a gap between the lower and upper semiconductor dies, the non-conductive fillet material further squeezing out of the gap horizontally and across sidewalls of the upper semiconductor die;
a dielectric layer disposed above the lower semiconductor die; and
a buffer layer disposed above the dielectric layer and at least partially underneath the squeezed out non-conductive fillet material.

12. The semiconductor device of claim 11, wherein the buffer layer surrounds the gap between the lower and upper semiconductor dies.

13. The semiconductor device of claim 11, wherein the buffer layer is made of organic polymer materials including benzocyclobutene (BCB) and Polyimide (PI), or dielectric materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

14. The semiconductor device of claim 11, further comprising an encapsulant material disposed on top surface of the upper semiconductor die and sidewalls of the lower and upper semiconductor dies, wherein the encapsulant material encapsulates the non-conductive fillet material, the dielectric layer, and the buffer layer.

15. A method of forming a semiconductor device, comprising:
preparing a lower semiconductor wafer having a dielectric layer disposed on its back side surface;
forming contact pads in a plurality of memory cube regions on the back side surface of the lower semiconductor wafer;
forming a buffer layer above the dielectric layer, the buffer layer surrounding one or more of the plurality of memory cube regions;
bonding a plurality of memory stacks on corresponding memory cube regions of the lower semiconductor wafer, each memory stack including one or more upper semiconductor dies; and
flowing a non-conductive fillet material into the bonded plurality of memory stacks and the lower semiconductor wafer, the non-conductive fillet material squeezing out of gaps between the plurality of memory stacks and the lower semiconductor wafer,
wherein the buffer layer is in contact to and disposed under at least a portion of the squeezed out non-conductive fillet material.

16. The method of claim 15, further comprising:
singulating, along tracks between the memory cube regions, the lower semiconductor wafer into lower semiconductor dies, each lower semiconductor die having a corresponding memory stack bonded thereon; and
coating an encapsulant material on sidewalls and top surface of the memory stack, the encapsulant material encapsulating the lower semiconductor die, the dielectric layer, the buffer layer, and the squeezed out non-conductive fillet material.

17. The method of claim 15, wherein forming the buffer layer includes:
forming a first hard mask layer on the back side surface of the lower semiconductor wafer,
patterning the first hard mask layer to expose the dielectric layer among the memory cube regions of the lower semiconductor wafer,
deposit the buffer layer on the exposed dielectric layer, and
removing the first hard mask layer from the lower semiconductor wafer.

18. The method of claim 15, wherein forming the buffer layer includes:
depositing the buffer layer on the back side surface of the lower semiconductor wafer,
planarizing the buffer layer to expose top surfaces of the contact pads,
coating a second hard mask layer above the buffer layer on the backside surface of the lower semiconductor wafer,
patterning the second hard mask layer to expose the plurality of memory cube regions,
removing the buffer layer from exposed plurality of memory cube regions, and
removing the second hard mask layer from the lower semiconductor wafer.

19. The method of claim 16, wherein singulating the lower semiconductor wafer includes cutting the semiconductor wafer through the buffer layer and the dielectric layer disposed on the back side surface of the lower semiconductor wafer, and wherein the buffer layer is adhesive to the at least a portion of the squeezed out non-conductive fillet material and is configured to prevent underneath dielectric layer from cracking or delamination from the lower semiconductor wafer.

20. The method of claim 16, wherein the plurality of memory stacks are bonded to the lower semiconductor wafer through a thermal compression bonding technique, wherein the non-conductive fillet material is cured to fill in the gap between the lower semiconductor wafer and the plurality of memory stacks, and wherein the squeezed out non-conductive fillet material is partially cured.
